(19) United States
(12) Patent Application Publication
(10) Pub. No.: US 2007/0188990 A1
(43) Pub. Date: Aug. 16, 2007

(54) Enclosure arrangement for an electronic device

(76) Inventor: Patrick Wallace, San Jose, CA (US)

Correspondence Address: FAY KAPLUN & MARCIN, LLP, 15O BROADWAY, SUITE 702, NEW YORK, NY, 10038, US

(21) Appl. No.: 11/345,450

(22) Filed: Feb. 1, 2006

(51) Int. Cl. H05K 7/20

(52) U.S. Cl. 361/688

(57) ABSTRACT

Described are is an enclosure arrangement for an electronic device. The arrangement comprises an electronic device enclosure including a heat transfer device (“HTD”) forming part of a wall thereof. The HTD includes a first panel internal to the enclosure and a second panel external to the enclosure. When in a first operating mode, the HTD absorbs heat from an interior of the enclosure and releases heat into an exterior of the enclosure, and in a second operating mode, the HTD absorbs heat from the exterior of the enclosure and releases heat into the interior of the enclosure air adjacent to the first panel and releases heat into air adjacent to the second panel.

### FIELD OF INVENTION

The present invention generally relates to protective device enclosures.

### BACKGROUND INFORMATION

Wireless networks are often deployed in both indoor and outdoor environments to extend coverage and functionality for the network. For example, a warehouse may utilize indoor access points (APs) providing network access for employees performing inventory functions within the warehouse, e.g., scanning barcodes on items, palates, etc. Additionally, the warehouse may utilize outdoor APs in a shipping yard providing network access for employees performing tracking functions outside the warehouse, e.g., scanning barcodes on items to indicate delivery/receipt thereof.

The outdoor APs, in contrast to the indoor APs, are in an environmentally dynamic environment due to weather and temperature changes. Barriers have been developed for protecting the outdoor APs from adverse weather conditions, e.g., rain, sleet, hail, snow, wind, etc. However, these barriers typically do not compensate for temperature variations and/or extremes. For example, shipping yards in Arizona may experience daily temperatures which routinely surpass 100° F., while temperatures in shipping yards in Wisconsin may fall below 0° F. At temperature extremes, an operational capacity of the AP may be significantly degraded and/or terminated.

### SUMMARY OF THE INVENTION

The present invention relates to an enclosure arrangement for an electronic device. The arrangement comprises an electronic device enclosure including a heat transfer device (“HTD”) forming part of a wall thereof. The HTD includes a first panel internal to the enclosure and a second panel external to the enclosure. When in a first operating mode, the HTD absorbs heat from an interior of the enclosure and releases heat into an exterior of the enclosure, and in a second operating mode, the HTD absorbs heat from the exterior of the enclosure and releases heat into the interior of the enclosure air adjacent to the first panel and releases heat into air adjacent to the second panel.

### BRIEF DESCRIPTION OF DRAWINGS

FIG. 1 shows an exemplary embodiment of an enclosure arrangement of an electronic device according to the present invention;

FIG. 2 shows an exemplary embodiment of a temperature sensing circuit according to the present invention; and

FIG. 3 shows an exemplary embodiment of a method according to the present invention.

### DETAILED DESCRIPTION

The present invention may be further understood with reference to the following description and the appended drawings, wherein like elements are provided with the same reference numerals. The present invention describes an enclosure arrangement for a device. In the exemplary embodiment, the enclosure arrangement protects a wireless access point (AP) from adverse weather conditions, and maintains a temperature within the enclosure within a predefined range selected based on an effective operating temperature of the AP. While the exemplary embodiment is described with respect to the AP, those of skill in the art will understand that the enclosure may vary in size and/or shape for receiving any electronic device therein. The electronic device may include, but is not limited to, the AP, a switch, a hub, a router, a speaker or any other electronic device operated in an outdoor environment.

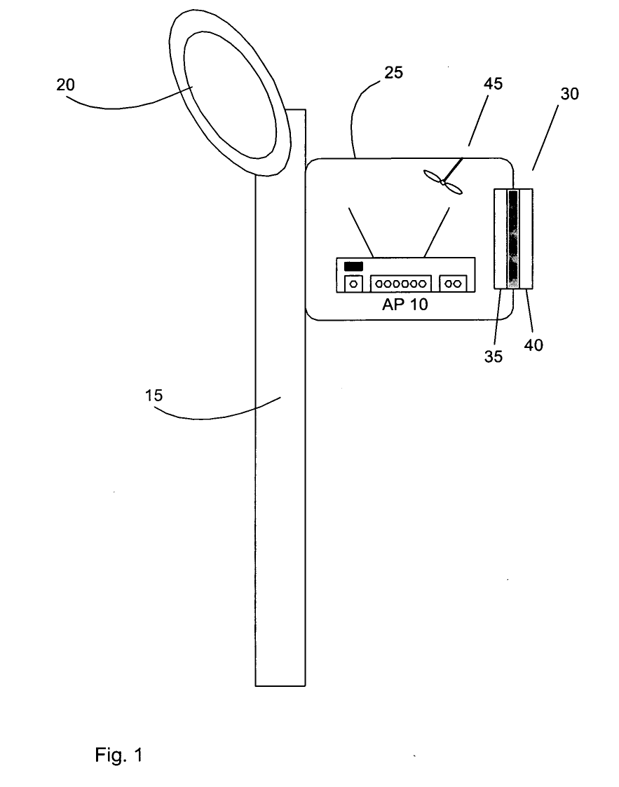

FIG. 1 shows an exemplary embodiment of an enclosure arrangement according to the present invention. When a wireless communication network is deployed in or extended to an outdoor environment (e.g., a shipping yard, a parking lot, a field, a city, etc.), network infrastructure devices are typically mounted on tall, immovable structures. For example, in the shipping yard the network infrastructure device, e.g, an access point (AP) 10, may be mounted on a top portion of a light pole 15. Those of skill in the art will understand that the AP 10 is typically mounted on the top portion (e.g., approximately 20 ft. off the ground) to extend a range of and reduce interference for radio frequency signals received and transmitted by the AP 10. The AP 10 may draw power from a line voltage which is supplied to a light 20 and/or a battery. When the AP 10 is equipped to draw power from the line voltage and the battery, the battery may be used as an emergency power source if the line voltage ever fails.

The AP 10 provides access to the network for mobile computing units (MUs) in the outdoor environment. The MUs may include, but are not limited to, laser-/image-based scanners, RFID readers/tags, PDAs, phones, tablets, laptops, VRCs, etc. In one exemplary embodiment, the AP 10 is connected to the network via an Ethernet cable which may be coupled to, for example, a switch, connecting the AP 10 to a server on the network. In an alternative embodiment, the AP 10 may be a node in a wireless mesh (e.g., multipoint bridging) which provides access to the network. In this embodiment, the cost associated with running Ethernet cables throughout the shipping yard may be reduced and/or eliminated.

According to the present invention, an enclosure arrangement 25 is provided for protecting the AP 10 from, for example, adverse weather conditions, corrosive environments (e.g., sea salt spray, dust/sand, fumes/gases, etc.), ice/snow/rain, sprayed water from washing vehicles or cleaning the light 20, etc. In the exemplary embodiment, the enclosure 25 is mounted to the light pole 15 and utilizes a box-like configuration for encasing the AP 10. The enclosure 25 may have a hinged side which opens allowing the AP 10 to be inserted therein and removed therefrom for maintenance, upgrading, etc. While the enclosure 25 and the AP 10 are described as separate items, those of skill in the art will understand that the enclosure 25 and the AP 10 may be integrally connected. That is, the AP 10 may be permanently mounted in the enclosure 25 with ports being provided to allow the AP 10 to connect to the line voltage and/or the Ethernet cable.

When sealed, the enclosure 25 is preferably water tight to withstand several ratings of water and ice, as provided in, for example, a National Electrical Manufacturers Association (NEMA) standard (e.g., NEMA 250-2003 “Enclosures for Electrical Equipment (1000 Volts Maximum)). That is, the enclosure 35 may have a predetermined NEMA rating such as, for example, NEMA 3, NEMA 3R, NEMA 3S, NEMA 4, NEMA 4X and NEMA 6. While the enclosure 25 protects the AP 10 from an external environment, variations in an internal environment (esp. temperature) may lead to performance degradation and/or malfunction if left unregulated. That is, the wireless network infrastructure devices typically have a defined operating temperature range detailed in their technical specifications thereof. For example, if the AP 10 utilizes an internal antenna, the operating temperature range may be from approximately 32° F.-104° F. If the AP 10 utilizes an external antenna, the range is extended, e.g., approximately −4° F.-122° F. Those of skill in the art will understand that the operating temperature range may be determined based on a type of the electronic device encased within the enclosure 25. For example, the operating temperature range for a wireless switch may be approximately 50° F.-95° F., which is substantially different from the AP 10, especially at a lower limit thereof. When an internal temperature within the enclosure 25 approaches, reaches and/or surpasses the lower limit or an upper limit, performance of the device is significantly impacted.

Conventionally, a “hot” environment is dealt with by placing an air conditioning unit adjacent the enclosure 25, while a “cold” environment is compensated for with a heating unit. For example, when the shipping yard is located in New Mexico (e.g., the hot environment), the air conditioning unit is either placed within or outside of the enclosure 25. However, these units are expensive, large, heavy, contain many moving parts/liquids and draw a significant amount of power. Also, when placed outside of the enclosure 25, the units themselves are susceptible to adverse weather conditions.

According to the present invention, a heat transfer device 30 is embedded in a wall of the enclosure 25. In the exemplary embodiment, the heat transfer device 30 is a thermionic device, such as a Peltier device. As known by those of skill in the art, the Peltier device includes two panels which sandwich a series of semiconductors (e.g., p-type and n-type semiconductors in a predefined arrangement). When a first current is applied to the heat transfer device 30 to generate a first polarity, heat is absorbed from air adjacent a first panel 35 and released into air adjacent a second panel 40. When a second current is applied to the heat transfer device 30 to generate a second polarity, heat is absorbed from air adjacent the second panel 40 and released into air adjacent the second panel 40. Thus, the heat transfer device 30 may be used alternately to heat and cool an air cavity inside the enclosure 25 as a function of the supplied current. The current may be supplied by the line voltage which supplies power to the light 20 on the light pole 15. If the heat transfer device 30 utilizes its own dedicated power source (e.g., battery, separate line voltage), it is preferred that the dedicated power source be mounted outside of the enclosure 25, optionally in a further weather-resistant enclosure. In this manner, any additional heating effect from consumption of power to the heat transfer device 30 is not added to any heat load within the enclosure 25, which may be problematic in the hot environment.

In an alternative embodiment, the first and/or second panels 35, 40 may include a heat sink (e.g., pins, fins, etc.) for increasing the rate of heat transfer between the inside of the enclosure 25 and the environment. That is, in the embodiment shown in FIG. 1, the heat sink on the first panel 35 may more effectively couple the first panel 35 to air inside the enclosure 30, while the heat sink on the second panel 40 couples the second panel 40 to air in the environment. Preferably, the heat sink is manufactured from a material which effectively conducts heat, e.g., aluminum, copper, etc., and is resistant (through selection of base materials, properties or coatings) to environmental corrosion conditions equal to the associated enclosure.

In a further exemplary embodiment, one or more fans 45 may be installed within the enclosure 25 to circulate air past the heat transfer device 30 and the AP 10. The fan 45 may be powered by the line voltage and/or a battery.

In operation, the heat transfer device 30 may be continually powered while the AP 10 is powered. In another exemplary embodiment, the heat transfer device 30 may be manually switched on and off, and/or controlled for heat transfer functionality (e.g., for cooling/warming the air cavity within the enclosure 25). For example, when the environmental temperature reaches a predetermined value, an employee may power up the heat transfer device 30. The predetermined value may be an environmental temperature value which corresponds to the inner temperature inside the enclosure 25 which is near, equal to or exceeds the upper/lower limit of the operating temperature of the AP 10.

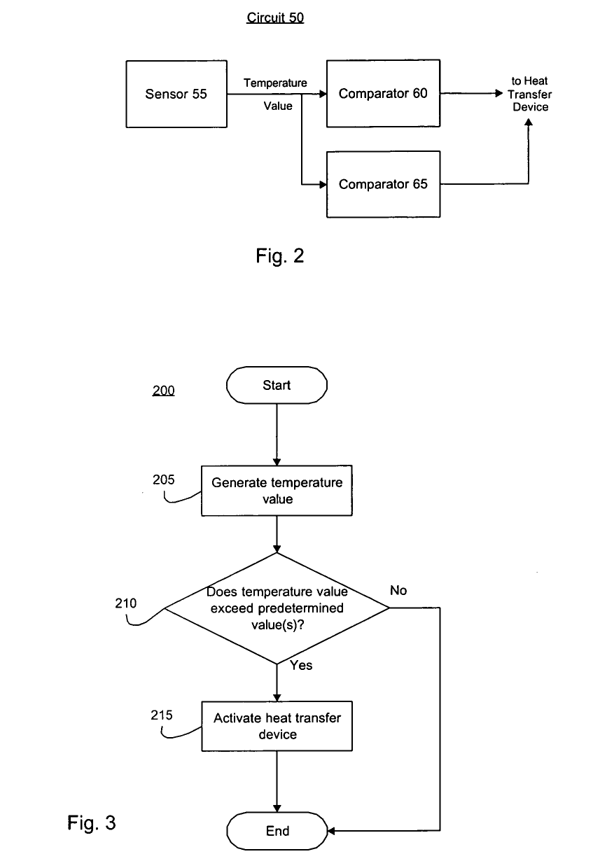

In another exemplary embodiment, a temperature sensing circuit 50 may be utilized to control operation of the heat transfer device 30. As shown in FIG. 2, an exemplary embodiment the circuit 50 includes a sensor 55, a first comparator 60 and a second comparator 65. A temperature value generated by the sensor 55 is compared against the upper and/or lower limits of the operating temperature range of the AP 10. When the upper limit is exceeded, the circuit instructs the heat transfer device 30 to activate and expel heat from the air within the enclosure 25 (i.e., a first polarity). When the lower limit is exceeded, the circuit instructs the heat transfer device 30 to activate and influx heat to the air within the enclosure 25 (i.e., a second polarity). In this embodiment, the heat transfer device 30 may draw less power than when continually powered.

FIG. 3 shows an exemplary embodiment of a method 200 for activating the heat transfer device 30. In step 205, the sensor 55 generates the temperature value corresponding to the inner temperature within the enclosure 25. In step 210, the temperature value is passed to the comparators 60 and 65, which determine whether the temperature value exceeds a predetermined value(s) selected based on, for example, the surrounding climate and the operating temperature range of the AP 20. For example, the predetermined values may include values substantially equal to (or a predetermined number of degrees lower, as determined by system hysteresis and/or latency) the upper limit of the operating temperature range of the AP 20, and substantially equal to (or a predetermined number of degrees higher, as determined by system hysteresis and/or latency) the lower limit operating temperature range of the AP 20.

If the temperature value exceeds the either of the predetermined values, the circuit 50 transmits an activation signal to the heat transfer device 30 (step 215). For example, if the temperature value exceeds the upper limit, the activation signal instructs the heat transfer device 30 to remove heat from the air within the enclosure 25. When the temperature value exceeds the lower limit, the activation signal instructs the heat transfer device 30 to add heat to the air within the enclosure 25. Thus, the activation signal may be generated as a function of the comparison of the temperature value to the upper and/or lower limits.

While the exemplary embodiment describes the circuit 50 controlling operation of the heat transfer device 30, those of skill in the art will understand that a software application executed on a remote server may control the heat transfer device 30. For example, the sensor 55 may utilize a wireline connection or a radio frequency transmitter for sending the detected temperature values to the server. The server may then remotely activate the heat transfer device 30. Further, as part of a wired network, connected to the co-installed access point, the system functionality may be monitored, modified and/or edited based on current and/or predicted changes in demand and/or environment.

The present invention allows network operators to deploy network infrastructure devices in any climate without having to be concerned about an effect of the climate on operation of the devices. Additionally, a heat transfer device may alleviate the costs and power requirements of air conditioners and/or heaters. For example, the present invention reduces installation weight of an environmentally protective enclosure. That is, the present invention may not require compressors, evaporators, condensers, high and low pressure plumbing, ducting and/or fluid coolants for heat transfer. Additionally, savings may be realized by eliminating maintenance/replacement costs associated with these components.

The present invention may also save on installation costs and time by using lightweight materials for the enclosure, including a temperature management system integral with the inclosure and reducing/eliminating pipe and/or duct installation. The present invention also provides increased mounting orientations and locations of electronic devices. Additionally, overall system power consumption may be reduced, because power may be directly applied to temperature control and management, eliminating parasitic losses in support systems and equipment.

One skilled in the art would understand that the present invention may also be successfully implemented in various other embodiments. Accordingly, various modifications and changes may be made to the embodiments without departing from the broadest spirit and scope of the present invention as set forth in the claims that follow. The specification and drawings are accordingly to be regarded in an illustrative rather than restrictive sense.

What is claimed is:

1. An arrangement, comprising:
an electronic device enclosure; and
a heat transfer device (“HTD”) forming part of a wall of the enclosure, the HTD including a first panel internal to the enclosure and a second panel external to the enclosure,
wherein, when in a first operating mode, the HTD absorbs heat from an interior of the enclosure and releases heat into an exterior of the enclosure, and in a second operating mode, the HTD absorbs heat from the exterior of the enclosure and releases heat into the interior of the enclosure.

2. The arrangement according to claim 1, wherein the electronic device is one of an access point, an access port, a switch, a hub, a router and a speaker.

3. The arrangement according to claim 1, wherein the enclosure includes an openable portion which, when closed, creates a watertight seal around the electronic device.

4. The arrangement according to claim 1, wherein the enclosure has a predetermined NEMA-rating.

5. The arrangement according to claim 4, wherein the predetermined NEMA-rating is one of NEMA 3, NEMA 3R, NEMA 3S, NEMA 4, NEMA 4X and NEMA 6.

6. The arrangement according to claim 1, further comprising:
a temperature sensing circuit controlling activation of the HTD, the circuit comprising a sensor measuring a temperature of an air cavity within the enclosure and a comparator comparing the temperature to at least one predefined temperature,
wherein, the circuit activates the HTD in one of the first and second operating modes as a function of the temperature.

7. The arrangement according to claim 6, wherein the at least one predefined temperature includes an upper threshold limit and a lower threshold limit based on corresponding upper and lower operating temperature limits of the electronic device.

8. The arrangement according to claim 7, wherein, when the temperature exceeds the upper threshold limit, the HTD activates in the first operating mode, and, when the temperature is lower than the lower threshold limit, the HTD activates in the second operating mode.

9. The arrangement according to claim 1, further comprising:
a fan within the enclosure.

10. The arrangement according to claim 1, wherein at least one of the first and second panels includes a heat sink.

11. The arrangement according to claim 1, wherein the HTD is a thermionic device.

12. The arrangement according to claim 11, wherein the thermionic device is a Peltier device.

13. A method, comprising:
providing an electronic device enclosure, the enclosure including a heat transfer device (“HTD”) forming part of a wall thereof, the HTD including a first panel internal to the enclosure and a second panel external to the enclosure;
positioning the electronic device within the enclosure;
measuring a temperature of an air cavity within the enclosure; and
activating the HTD in one of first and second operating modes as a function of the temperature.

14. The method according to claim 13, wherein the activating step includes the following substeps:
when the temperature is greater than a first predetermined value, activating the HTD to absorb heat from an interior of the enclosure and release heat into an exterior of the enclosure; and
when the temperature is lower than a second predetermined value, activating the HTD to absorb heat from the exterior of the enclosure and release heat into the interior of the enclosure.

15. The method according to claim 13, wherein the electronic device is one of an access point, an access port, a switch, a hub, a router and a speaker.

16. The method according to claim 13, wherein the enclosure has a predetermined NEMA-rating.

17. The method according to claim 16, wherein the predetermined NEMA-rating is one of NEMA 3, NEMA 3R, NEMA 3S, NEMA 4, NEMA 4X and NEMA 6.

18. The method according to claim 14, wherein the first and second predetermined values are based on upper and lower operating temperature limits, respectively, of the electronic device.

19. The method according to claim 13, further comprising:
activating a fan within the enclosure.

20. A system, comprising:
a server;
an access point coupled to the server; and
an access point enclosure including a heat transfer device (“HTD”) forming part of a wall thereof, the HTD including a first panel internal to the enclosure and a second panel external to the enclosure,
wherein, when in a first operating mode, the HTD absorbs heat from an interior of the enclosure and releases heat into an exterior of the enclosure, and in a second operating mode, the HTD absorbs heat from the exterior of the enclosure and releases heat into the interior of the enclosure, and
wherein the server measures a temperature within the enclosure and activates the HTD in one of the first and second operating modes as function of the temperature.

21. The system according to claim 20, wherein the enclosure has a NEMA-rating of one of NEMA 3, NEMA 3R, NEMA 3S, NEMA 4, NEMA 4X and NEMA 6.

22. The system according to claim 20, wherein, when the temperature is greater than a first predetermined value, the server activates in the first operating mode, and when the temperature is lower than a second predetermined value, the server activates in the second operating mode.

23. An arrangement, comprising:
an enclosing means for enclosing an electronic device therein;
a temperature sensing means for measuring a temperature of an air cavity within the enclosing means;
a heat transfer means for adjusting the temperature within the air cavity; and
an activation means for activating the heat transfer means as a function of the temperature.
